(19) United States
(12) Patent Application Publication
(10) Pub. No.: US 2008/0146014 A1
(43) Pub. Date: Jun. 19, 2008

(54) SELF ALIGNED CONTACT

(76) Inventor: Yi Ding, San Jose, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/610,948

(22) Filed: Dec. 14, 2006

(51) Int. Cl. H01L 21/44

(52) U.S. Cl. 438/597

(57) ABSTRACT

A semiconductor device comprises one or more self aligned contacts. The device may include one or more gate structures adjacent a first doped region. The device may comprise a first dielectric overlaying the gate structure and a first layer comprising silicon and overlaying a top of each said gate structure, the first layer being separated from each said conductive gate by the first dielectric. The first layer having an opening overlying the first doped region, and the first dielectric extends substantially down side portions of the opening. The device includes a first conductive contact having at least a portion extending into the opening, the contact electrically contacting the first doped region at a bottom region of the opening, the contact being insulated each conductive gate of each gate structure adjacent to the contact by the first dielectric.

### FIELD OF INVENTION

This invention relates to integrated circuits and, more particularly, to self-aligned contacts for semiconductor structures.

### BACKGROUND

Forming reliable contact structures for semiconductor devices becomes more difficult as feature sizes decrease, and as the device density on the chip increases. For example, the aspect ratio (ratio of depth to width) of contact structures increases as the device density increases. As a result, it becomes increasingly difficult to perform the contact etch to the required depth without over-etching in a lateral direction.

In order to more reliably fabricate smaller semiconductor device structures at higher density, self-aligned contacts may be used. Self-aligned contacts improve not only the physical characteristics of the contact, but the electrical characteristics as well. Self-aligned contacts use material properties of the structures themselves to prevent or reduce the occurrence of some process errors, such as those described above.

FIGS. 1A-1C are a simplified illustration of a prior art process forming a self-aligned contact to a source/drain region shared by two adjacent transistors. A silicon dioxide layer 110 (gate oxide) is formed on a silicon substrate 120. A polysilicon layer 130 (gate polysilicon) is formed on oxide 110. A protective dielectric 140 is formed on polysilicon 130. Dielectric 140 typically includes a silicon nitride layer to protect the gates during a subsequent etch of a self-aligned source/drain contact opening. Dielectric 140 and polysilicon 130 are patterned using a single photolithographic mask (not shown) to define the transistor gates. The structure is heated to oxidize the sidewalls of polysilicon 130 and thus form silicon oxide layer 144 on the sidewalls.

Dielectric spacers 150 (FIG. 1B) comprising silicon nitride are formed over the sidewalls of gates 130 and features 140. Spacers 150 include a layer deposited and etched anisotropically without a mask. One or more doping steps (e.g., implant steps) are performed to form source/drain regions 160 (i.e. 160.1, 160.2, 160.3). The structure is heated to anneal the source/drain regions. Oxide 110 is generally removed after the source/drain implant step.

Thick interlayer dielectric (ILD) 170 is formed on the structure from silicon dioxide. ILD CMP (chemical mechanical polishing) is then performed to substantially planarize the surface prior to the subsequent contact masking process. A photoresist layer 180 (FIG. 1C) is formed on oxide 170 and photolithographically patterned to have an opening over the source/drain region 160.2 shared by the two transistors. The opening in the photoresist can overlap the transistor gates 130.

Oxide 170 is etched through the photoresist opening. As a result, an opening is formed in oxide 170 to expose the source/drain region 160.2 (oxide 110 may also have to be removed if it has not been removed over the source/drain region 160.2 in an earlier step, e.g. the step immediately after the patterning of polysilicon 130 at the stage of FIG. 1A). The oxide etch is selective to silicon nitride. The gates 130 are protected by the nitride in layers 140, 150 and hence are not exposed. The photoresist is removed, and a conductive layer (not shown) is deposited into the opening in oxide 170 to provide a contact to the source/drain region 160.2. See e.g. U.S. Pat. No. 6,573,602 issued Jun. 3, 2003 to Seo et al.

### SUMMARY

This section summarizes some features of the invention. Other features are described below. The invention is defined by the appended claims.

In general, in one aspect, a method comprises providing a substrate comprising a first doped region selected from the group consisting of a doped source region and a doped drain region, providing a first gate structure having a top surface and a side surface adjacent the top surface of the first gate structure and extending down toward the first doped region, and providing a second gate structure having a top surface and side surfaces adjacent the top surface of the second gate structure and extending down toward the first doped region.

The method may further comprise depositing a first layer over the top surface of the first gate structure, the side surface of the first gate structure, the first doped region, the side surface of the second gate structure, and the top surface of the second gate structure to form an opening. The method may further comprise depositing a second material in the opening over the first doped region, the second material defining a contact etch region. The method may further comprise providing a third material over the top surface of the first gate structure and the second gate structure but not over the first doped region, and removing the second material from the opening.

Providing the third material over the top surface of the first gate structure and the second gate structure but not over the first doped region may comprise depositing a layer of the third material over the top surface of the first gate structure, the second material, and the top surface of the second gate structure and removing the third material over the second material.

The method may further comprise depositing a dielectric into the opening and over the top surface of the first gate structure and the second gate structure. The method may further comprise etching a portion of the dielectric to a level proximate the first doped region to form an opening, and may comprise depositing a contact material into the opening. The method may further comprise, prior to depositing the contact material into the opening, removing contact stop material formed over the first doped region.

In some embodiments, the first doped region comprises a doped silicon portion adjacent a silicide contact region. The first gate structure may comprise a polysilicon gate portion adjacent a silicide contact region.

In general, in another aspect, an integrated circuit may comprise one or more gate structures, each said gate structure comprising at least one conductive gate. The circuit may further comprise a first doped region selected from a doped source region and a doped drain region, the first doped region being adjacent to a sidewall of at least one of said one or more gate structures. The circuit may further comprise a first dielectric overlaying each said gate structure, and a first layer overlaying a top of each said gate structure, the first layer being separated from each said conductive gate by the first dielectric. The first layer may have an opening therethrough, wherein the opening overlies the first doped region, and wherein the first dielectric extends substantially down side portions of the opening. The circuit may further comprise a first conductive contact having at least a portion extending into the opening, the contact electrically contacting the first doped region at a bottom region of the opening, the contact being insulated each conductive gate of each gate structure adjacent to the contact by the first dielectric. The circuit may further comprise a second doped region selected from a doped source region and a doped drain region, wherein the first layer overlies the second doped region.

In some embodiments, each gate structure may include metal silicide. The first dielectric may comprise silicon.

The contact may be formed by etching through another material using an etchant that is selective of the another material with respect to the first dielectric. The gate structure may comprise a first conductive gate and a second conductive gate separated by an insulating material. The doped region may comprise an N+ doped drain region.

In general, in another aspect, a semiconductor device comprises one or more gate structures, each of said gate structure comprising at least one conductive gate. The device may further comprise a first doped region selected from a doped source region and a doped drain region, the first doped region being adjacent to a sidewall of at least one of said one or more gate structures. The device may further comprise a first dielectric overlaying each said gate structure and a first layer overlaying a top of each said gate structure, the first layer being separated from each said conductive gate by the first dielectric. The first layer may have an opening therethrough, wherein the opening overlies the first doped region, and wherein the first dielectric extends substantially down side portions of the opening. The device may further comprise a first conductive contact having at least a portion extending into the opening, the contact electrically contacting the first doped region at a bottom region of the opening, the contact being insulated each conductive gate of each gate structure adjacent to the contact by the first dielectric.

These and other features and advantages of the present invention will be more readily apparent from the detailed description of the exemplary implementations set forth below taken in conjunction with the accompanying drawings.

### BRIEF DESCRIPTION OF THE DRAWINGS

FIGS. 1A-1C are vertical cross sections of integrated circuits to provide a simplified illustration of a prior art process for forming a self-aligned contact to a source/drain region shared by two adjacent transistors.

FIG. 2A shows a vertical cross-section of an integrated circuit during fabrication according to some embodiments of the present invention.

FIG. 2B is a plan view of the integrated circuit of FIG. 2A.

FIGS. 2C, 2D, 2E, 2F, 3A, 3B, 3C, and 3D show vertical cross-sections of integrated circuits during fabrication according to some embodiments of the present invention.

Like reference symbols in the various drawings indicate like elements.

### DETAILED DESCRIPTION

This section describes some embodiments of the invention. The invention is not limited to these embodiments. In particular, the materials used, the dimensions, and other features are not limiting unless required by the appended claims.

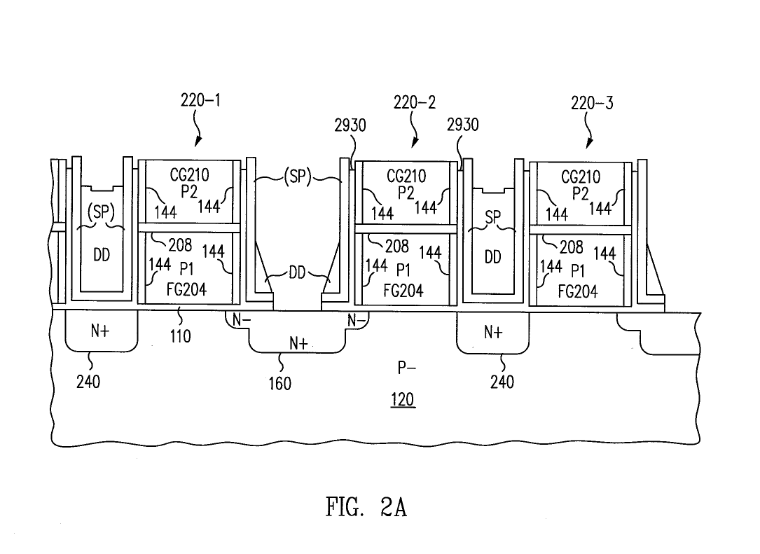

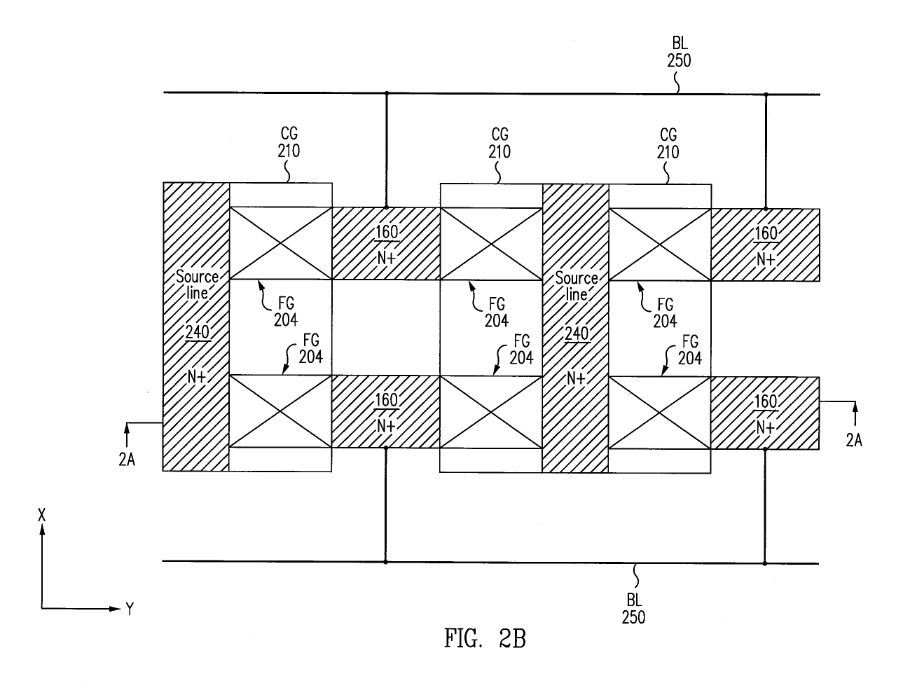

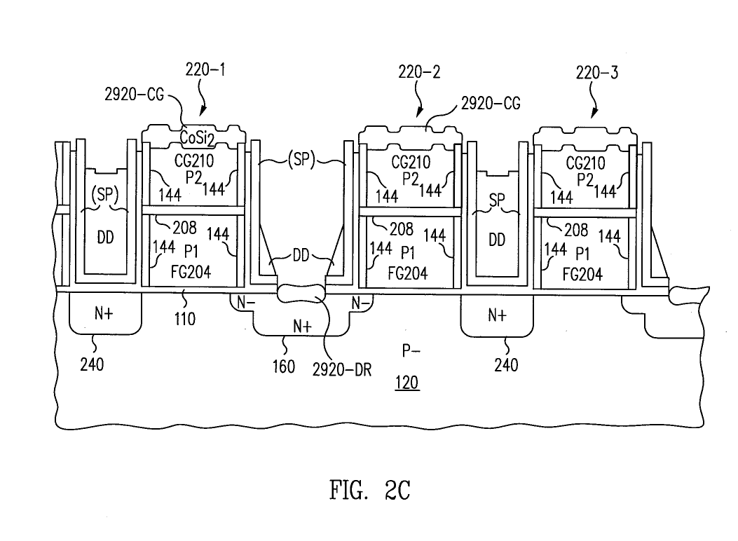

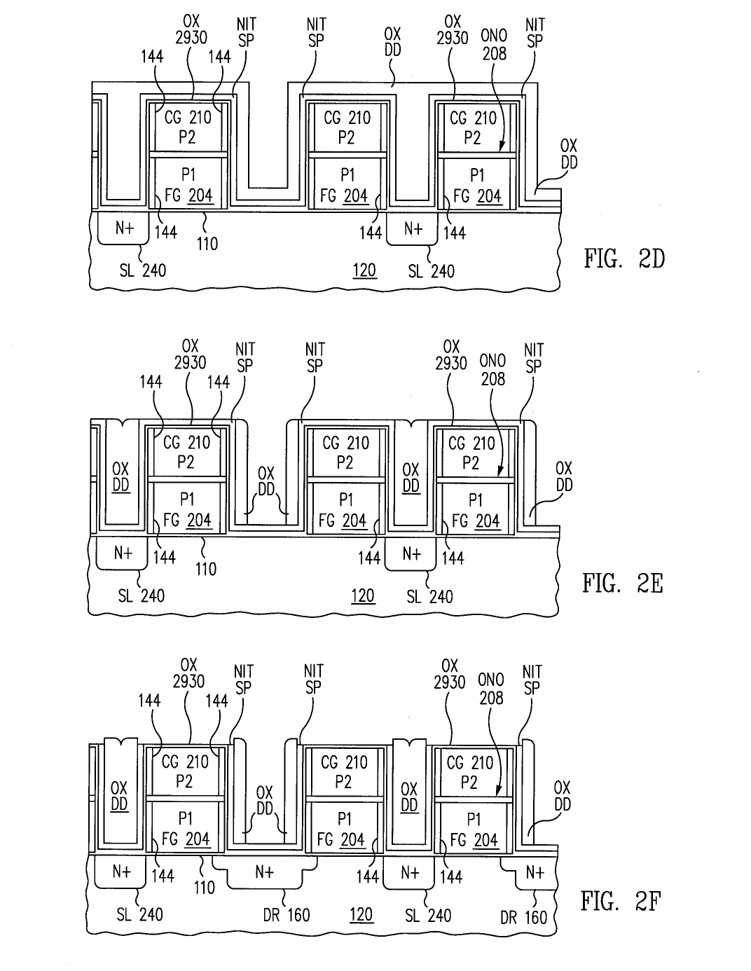

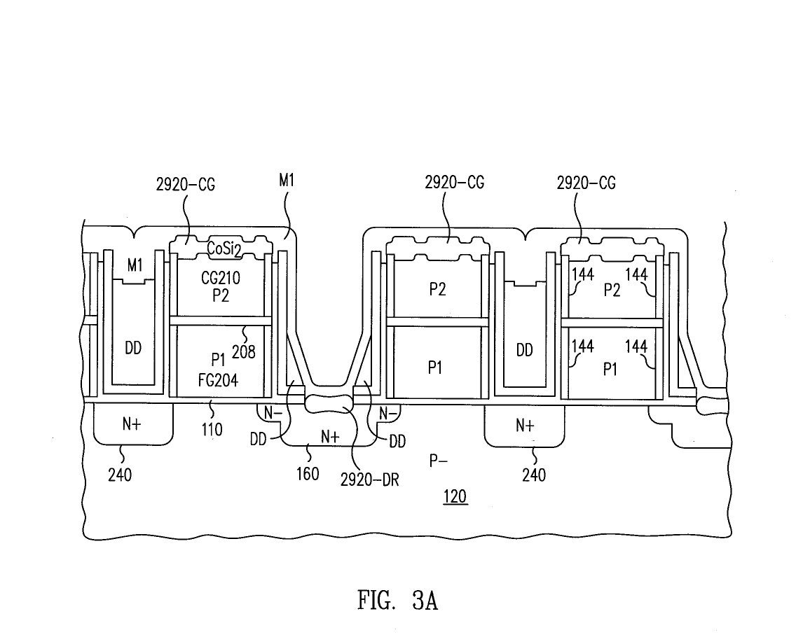

Systems and techniques provided herein provide improved self-aligned contact formation. FIGS. 2A, 2B illustrate an integrated circuit at an intermediate stage of fabrication according to one embodiment of the present invention. FIG. 2A shows a vertical cross section marked “2A” in the top view of FIG. 2B. FIG. 2B shows silicon features but does not show dielectric layers. The integrated circuit is an ETOX type flash memory, fabricated in and over a P doped region of a monocrystalline silicon substrate 120. (The invention is not limited to flash memories, silicon circuits, particular dimensions, and other features, except as defined by the appended claims.) ETOX memories are described, for example, in U.S. Pat. No. 5,751,631 issued May 12, 1998 to Liu et. al.; European patent application EP1426974, both incorporated herein by reference.

Silicon dioxide layer 110 (FIG. 2A) is formed on substrate 120. Oxide 110 includes gate oxide underneath floating gates (FG) 204 made from a doped polysilicon layer P1. The floating gates are marked with crosses in FIG. 2B. Dielectric 208 (e.g. ONO, i.e. a sandwich of silicon oxide, silicon nitride, silicon oxide) overlies the floating gates and separates them from control gates 210. Each memory cell includes a gate structure 220 (e.g. 220-1, 220-2, 220-3) which includes a floating gate 204 and a control gate 210.

As seen in FIG. 2B, each control gate 210 is part of a control gate line, marked with the same numeral 210, extending through the array in a row direction (X-direction). In this example, the control gate lines include a polysilicon layer P2 and a metal silicide (e.g. cobalt silicide) 2920-CG, shown in FIG. 2C, formed on polysilicon P2 to reduce the control gate resistance. FIG. 2C shows the same view as FIG. 2A after the metal silicide formation.

A source region 240 and a drain region 160 are N+ doped regions formed in substrate 120 on the opposite side of each gate structure 220. Drain regions 160 are silicided with a metal silicide (e.g. cobalt silicide) 2920 DR (FIG. 2C). All drain regions 160 in each column of memory cells are connected to a bitline 250 (schematically shown in FIG. 2B) extending in the column direction through the memory array. The bitlines have not been manufactured at the stage of FIGS. 2A-2C. Each drain region 160 is shared by two adjacent memory cells in the respective memory column. Each source region 240 is part of a source line 240 (FIG. 2B) running through the array in the row direction between adjacent control gate lines 210. Each source line is thus shared by two adjacent rows.

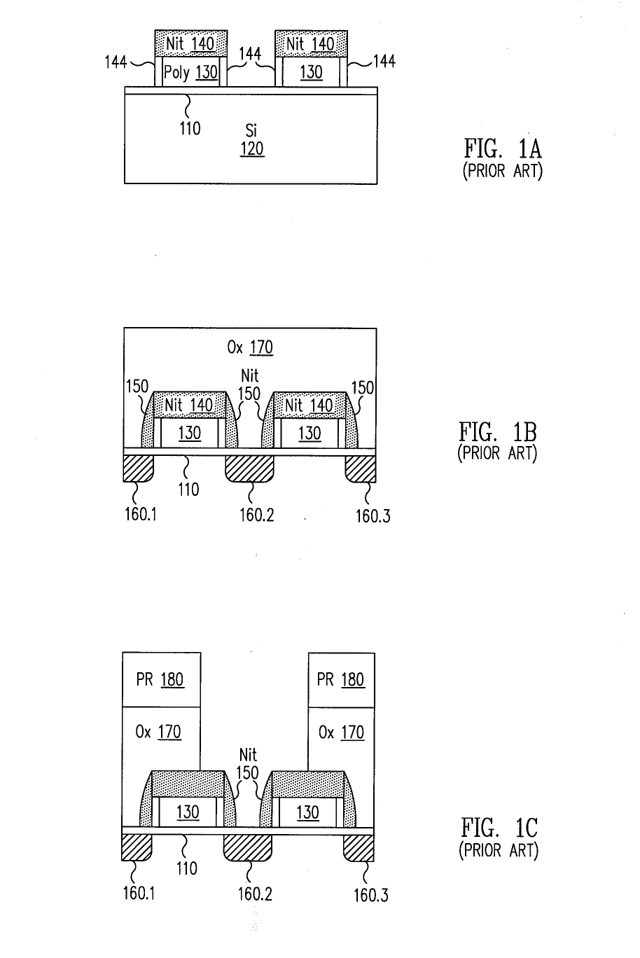

The sidewalls of floating gates 204 on the sides adjacent to source lines 240 and drain regions 160, and the sidewalls of polysilicon P2, are covered with silicon oxide 144. Each gate structure 220 includes a floating gate 204, the immediately underlying gate oxide 110, the immediately overlying portion of dielectric 208, the immediately overlying control gate 210 (a portion of control gate line), including the silicide 2920-CG, and the immediately adjacent sidewall oxide portions 144 will be referred to herein as a “gate structure”. Three gate structures 220 (220-1, 220-2, 220-3) are shown in FIG. 2A, and six gate structures are shown in FIG. 2B. In some embodiments, oxide 144 is omitted. Other variations are also possible for the gate structures. For example, a gate structure may have only one conductive gate (e.g. like in FIG. 1C).

In some illustrative embodiments of FIGS. 2A-2C, gate oxide 110 (underneath the floating gates 204) has a thickness of 85˜95 Å; layer P1 has thickness of 600˜800 Å, ONO 208 is 160˜180 Å thick (the equivalent oxide thickness of 130˜150 Å), and layer P2 is 600˜800 Å thick. Silicide 2920-CG is about 300 Å thick. The total height of each gate structure 220 is thus 1540˜1970 Å. The distance between the adjacent gate structures 220 sharing a drain region 160 (e.g. structures 220-1, 220-2) in the view of FIG. 2C is 0.22˜0.28 pm. The distance between the gate structures sharing a source region 240 e.g. structures 220-2, 220-3) is 0.1 pm.

Dielectric DD (FIGS. 2A, 2C) covers the substrate between control gates 210, except at the location of drain regions 160. The memory may also include field isolation (e.g. silicon dioxide, not shown) in areas not occupied by source lines 240 between adjacent memory columns.

In some embodiments, the memory is fabricated as illustrated in FIGS. 2D-2F. Silicon dioxide 110 is formed on substrate 120 by thermal oxidation. Doped polysilicon P1 is deposited and patterned as a number of long strips extending in the Y direction over the future positions of conductive floating gates 204 in each column. Substrate isolation regions can be formed before or after the polysilicon P1 deposition. For example, in some embodiments, the substrate isolation regions are formed using shallow trench isolation (STI). Substrate 120 is etched using the same mask as for polysilicon P1 (possibly a hard mask) to form trenches extending through the memory array in the column direction. The trenches are filled with dielectric. In other embodiments, substrate isolation is formed before the polysilicon deposition. These techniques are well known.

After the polysilicon P1 deposition and patterning, ONO 208 and conductive (doped) polysilicon P2 are deposited on the wafer. Polysilicon P2 is patterned photolithographically to form the polysilicon portions of control gate lines 210. Then ONO 208 and polysilicon P1 are etched away in the areas not covered by the control gate lines. Then thermal oxidation is performed to form silicon oxide 144 on the exposed sidewalls of layers P1 and P2. Oxide 144 can also be formed on the top of polysilicon P2, but this is not shown in the drawings. The thermal oxidation can be conducted at any suitable temperature, and in some embodiments the temperatures of 1000° C. or above are used to reduce the oxidation time. In some embodiments, oxide 144 is 30˜90 Å thick.

If the substrate isolation trenches extend through the array, the substrate isolation dielectric is etched out of the trenches at the locations of source lines 240. The etch is performed using a mask (not shown) which covers the areas between the control gate lines on the side of drain regions 160 but exposes the source lines 240. The mask does not have to be precisely aligned since the mask openings may overlap the gate structures.

Using the same mask, dopant is implanted into the wafer, e.g. by ion implantation, to dope the source lines 240 to N+.

Thin dielectric layer 2930 (FIGS. 2A, 2D), e.g. silicon dioxide, and then a thin silicon nitride layer SP, are deposited over the wafer. Dielectric DD is deposited over the wafer to fill the spaces between the control gate lines 210 over source lines 240 but not over drain regions 160. For example, dielectric DD can be silicon dioxide conformally deposited by CVD from TEOS to a thickness grater than one half of the distance between control gate lines 210 measured over source lines 240 but less than half the distance between control gate lines 210 measured over drains 160. Then dielectric DD is etched down anisotropically without a mask to a level at or slightly below the top surface of polysilicon P2 to form sidewall spacers over the future positions of drain regions 160 (see FIG. 2E). This etch stops on nitride SP over the drains 160 and control gate lines 210.

Nitride SP is etched away over the drain regions with oxide DD as a mask (FIG. 2F). Ion implantation is conducted to dope drain regions 160 to type N+. Then a thermal anneal is conducted, at an exemplary temperature of 1000˜1030° C. for 30 seconds, to activate the dopant in the drain regions and the source lines.

A short oxide etch (e.g. wet etch) removes silicon dioxide 2930 over polysilicon P2 and drain regions 160 (see FIG. 2A). If oxide 144 was formed on top of polysilicon P2 during the oxidation of polysilicon sidewalls, oxide 144 is removed from over polysilicon P2 by this etch. Some of oxide DD is also removed. Then self-aligned silicidation (also referred to as “salicidation”) is performed to form silicide 2920 CG, 2920-DR (FIG. 2C). Of note, in some embodiments, the silicide is cobalt silicide, which can be damaged by temperatures above 950° C.

After salicidation, a contact stop layer may optionally be deposited. The contact stop layer may be, for example, a very thin silicon nitride layer. The contact stop layer protects underlying material, such as silicide region 2920-DR, during the long dielectric etch in which the opening for the contact material is formed. Because of the duration of the etch, some portions of the underlying source and/or drain regions may be exposed before others, and may be damaged by the etch environment during the remainder of the etch. The contact stop layer allows the regions to be protected for the entire duration of the etch, and may subsequently be removed by a process such as a wet or dry etch. The contact stop layer enhances process uniformity control that may be affected due to loading effects and/or CMP process variation. Additionally, it can improve the contact etch in the unsilicided area.

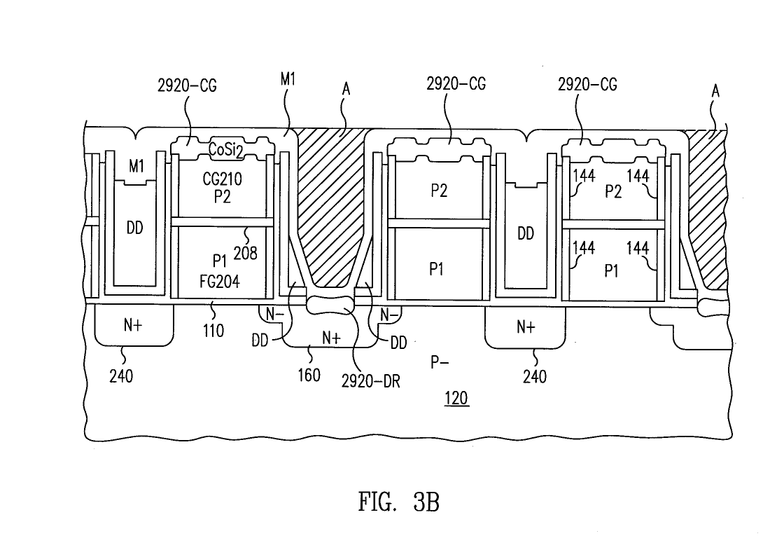

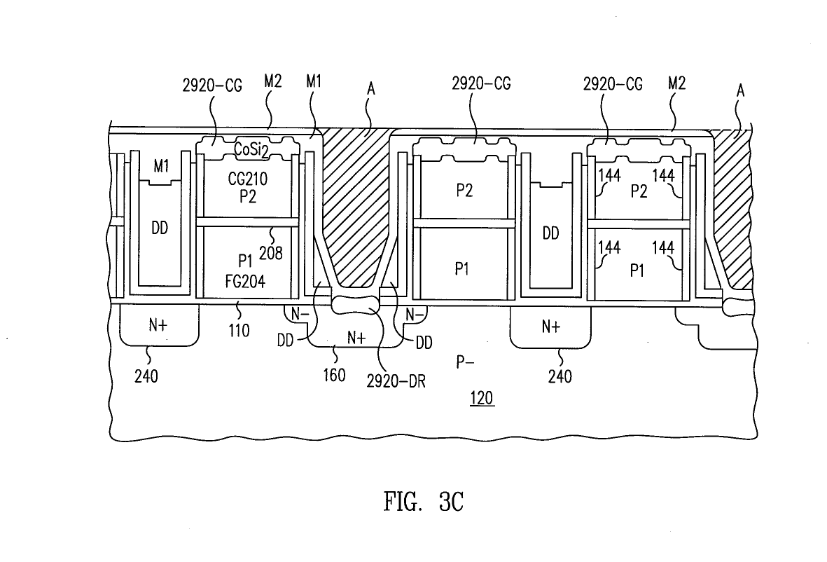

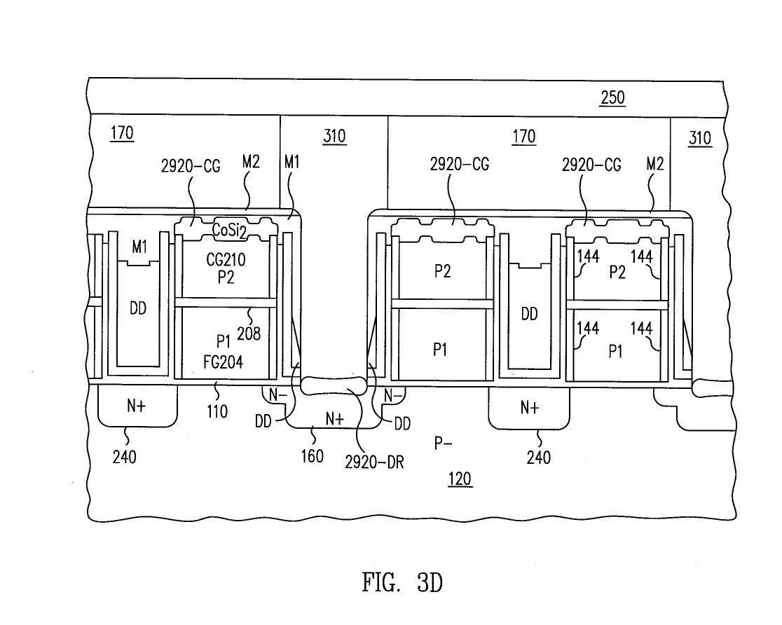

As shown in FIGS. 3A to 3D, a series of layers is then deposited on the structure of FIG. 2C. FIG. 3A shows the structure after deposition of a first layer M1 of undoped silicon glass (USG) or silicon dioxide deposited from tetra-ethyl-ortho-silicate (TEOS) using a plasma enhanced TEOS process (PETEOS). Layer Ml is deposited to form a recess region between adjacent gate structures and over a source/drain region. As shown in FIG. 3A, layer M1 may be conformal. For example, as illustrated in FIG. 3A, layer M1 may be deposited on a first gate structure on one side of a drain region, on a second gate structure on another (opposite) side of the drain region, on sidewalls of the first and second gate structures, and on a contact portion of the drain region, to form a recess region between the first and second gate structures.

Illustratively, layer M1 has a thickness of about 400˜500 Å. The M1 layer will protect the silicided layer 2920-CG atop the gate structures as well as the sidewall portions of layer SP at the sides of the gate structures from being eroded by subsequent etching steps. The M1 layer also serves as part of an isolation layer between to-be-formed drain contacts 310 (FIG. 3D) and the gate structures.

FIG. 3B shows the structure after deposition of material A, and an etch-back process to substantially planarize material A, stopping on M1. Material A comprises a material such as nitride, with different etch characteristics than those of M1. Material A fills the recess between adjacent gate structures, and serves to define a region through which the long contact etch will later be performed.

FIG. 3C shows the structure after M1 has been etched back a small distance, so that material A protrudes from the surface of M1. A different material M2 is then deposited, and etched back or polished to the level of material A. M2 is a material such as undoped silicon deposited using a PETEOS process, or other suitable material.

As FIG. 3C illustrates, M2 is positioned over the gate structures, and acts to protect M1 (and thus the gate structures) during the long etch in which the openings for the contacts are made. However, M2 is not positioned over the drain regions to which the contact etch will extend. Instead, material A is provided over those regions and acts as a mask defining the position of M2.

FIG. 3D shows the structure after material A is removed, and a relatively thick interlayer dielectric (ILD) layer 170 has been deposited. Layer 170 may be phosphosilicate glass (PSG), borophosphosilicate glass (BPSG), or undoped silicate glass (USG). Layer 170 may be deposited to an exemplary thickness of about 5600-8500 Å using HDP (high density plasma) or in a furnace. Layer 170 fills the gaps between the gate structures 220. Layer 170 can be deposited to have a planar top surface, or its top surface can be planarized by chemical mechanical polishing (CMP) or other known techniques to facilitate the application of a photoresist mask (not shown). The mask is formed on the wafer and patterned to expose the drain regions 160. Some embodiments use a hard mask (e.g., a hard mask comprising silicon) patterned using the photoresist mask. As explained in U.S. Pat. No. 6,193,870, the hard mask may be desirable for better protection of the ILD layer. The mask openings may overlap control gate lines 210 and may also overlap the substrate regions between drains 160 in each row.

An etch is then performed to expose the silicide 2920-DR over the drain regions 160. If desired, a layer of silicon oxide (not shown) may be non-conformally deposited (e.g., by CVD from TEOS) to line the walls of the resulting self-aligned contact opening. After the oxide is deposited, an anisotropic (preferentially vertical) oxide etch removes the bottom portion of the deposited oxide from the bottom of the contact openings to expose silicide 2920 DR. Some of the oxide layer remains on the openings' sidewalls to improve isolation between contacts 310 of FIG. 3D (see below) and the gates.

The contact openings to drain regions 2920-DR are then filled with conductive material 310. In some embodiments, material 310 includes a thin barrier layer of titanium/titanium nitride (Ti/TiN), and also includes a tungsten plug. In these embodiments, the tungsten is deposited after the barrier layer to fill the contact openings. The barrier layer and tungsten may then be substantially planarized using a chemical mechanical polishing (CMP) process (which also removes the hard mask, if used). A conductive layer 250 is then deposited and patterned to form the bitlines.

Advantageously, in some embodiments, the self-aligned method for forming the contact openings to the drain regions makes the contact areas between the silicide regions 2920 DR and contacts 510 uniformly large. A non-self-aligned method could make these areas smaller due to a possible shift of the contacts 510 relative to the drain regions.

In implementations, the above described techniques and their variations may be implemented at least partially as computer software instructions. Such instructions may be stored on one or more machine-readable storage media or devices and are executed by, e.g., one or more computer processors, or cause the machine, to perform the described functions and operations.

The invention is not limited to contacts to drain regions. Self-aligned contacts to source regions can be made using similar techniques. Also, the invention is not limited to non-volatile memories. In some embodiments, the contacts are made to source or drain regions of transistors such as shown in FIGS. 1A-1C. The invention is applicable to memories (e.g. DRAMS) and non-memory structures.

A number of implementations have been described. Although only a few implementations have been disclosed in detail above, other modifications are possible, and this disclosure is intended to cover all such modifications, and most particularly, any modification which might be predictable to a person having ordinary skill in the art.

Also, only those claims which use the word “means” are intended to be interpreted under 35 U.S.C. 112, sixth paragraph. In the claims, the word “a” or “an” embraces configurations with one or more element, while the phrase “a single” embraces configurations with only one element, notwithstanding the use of phrases such as “at least one of” elsewhere in the claims. Moreover, no limitations from the specification are intended to be read into any claims, unless those limitations are expressly included in the claims. Accordingly, other embodiments are within the scope of the following claims.

What is claimed is:

1. A method comprising:
providing a substrate comprising a first doped region selected from the group consisting of a doped source region and a doped drain region;
providing a first gate structure having a top surface and a side surface adjacent the top surface of the first gate structure and extending down toward the first doped region;
providing a second gate structure having a top surface and side surfaces adjacent the top surface of the second gate structure and extending down toward the first doped region;
depositing a first layer over the top surface of the first gate structure, the side surface of the first gate structure, the first doped region, the side surface of the second gate structure, and the top surface of the second gate structure to form an opening;
depositing a second material in the opening over the first doped region, the second material defining a contact etch region;
providing a third material over the top surface of the first gate structure and the second gate structure but not over the first doped region; and
removing the second material from the opening.

2. The method of claim 1, wherein providing the third material over the top surface of the first gate structure and the second gate structure but not over the first doped region comprises depositing a layer of the third material over the top surface of the first gate structure, the second material, and the top surface of the second gate structure and removing the third material over the second material.

3. The method of claim 1, further comprising depositing a dielectric into the opening and over the top surface of the first gate structure and the second gate structure.

4. The method of claim 3, further comprising etching a portion of the dielectric to a level proximate the first doped region to form an opening.

5. The method of claim 4, further comprising depositing a contact material into the opening.

6. The method of claim 5, further comprising, prior to depositing the contact material into the opening, removing contact stop material formed over the first doped region.

7. The method of claim 1, wherein the first doped region comprising a doped silicon portion adjacent a silicide contact region.

8. The method of claim 1, wherein the first gate structure comprises a polysilicon gate portion adjacent a silicide contact region.

9. An integrated circuit comprising:
one or more gate structures, each said gate structure comprising at least one conductive gate;
a first doped region selected from a doped source region and a doped drain region, the first doped region being adjacent to a sidewall of at least one of said one or more gate structures;
a first dielectric overlaying each said gate structure;
a first layer overlaying a top of each said gate structure, the first layer being separated from each said conductive gate by the first dielectric, the first layer having an opening therethrough, wherein the opening overlies the first doped region, and wherein the first dielectric extends substantially down side portions of the opening;
a first conductive contact having at least a portion extending into the opening, the contact electrically contacting the first doped region at a bottom region of the opening, the contact being insulated each conductive gate of each gate structure adjacent to the contact by the first dielectric.

10. The integrated circuit of claim 9, wherein each said gate structure includes metal silicide.

11. The integrated circuit of claim 9, further comprising a second doped region selected from a doped source region and a doped drain region, wherein the first layer overlies the second doped region.

12. The integrated circuit of claim 9, wherein the first dielectric comprises silicon.

13. The integrated circuit of claim 9, wherein the contact is formed by etching through another material using an etchant that is selective of the another material with respect to the first dielectric.

14. The integrated circuit of claim 9, wherein the gate structure comprises a first conductive gate and a second conductive gate separated by an insulating material.

15. The integrated circuit of claim 9, wherein the doped region comprises an N+ doped drain region.

16. A semiconductor device comprising:
one or more gate structures, each of said gate structure comprising at least one conductive gate;
a first doped region selected from a doped source region and a doped drain region, the first doped region being adjacent to a sidewall of at least one of said one or more gate structures;
a first dielectric overlaying each said gate structure;
a first layer overlaying a top of each said gate structure, the first layer being separated from each said conductive gate by the first dielectric, the first layer having an opening therethrough, wherein the opening overlies the first doped region, and wherein the first dielectric extends substantially down side portions of the opening;
a first conductive contact having at least a portion extending into the opening, the contact electrically contacting the first doped region at a bottom region of the opening, the contact being insulated each conductive gate of each gate structure adjacent to the contact by the first dielectric.

17. The device of claim 16, wherein each said gate structure includes metal silicide.

18. The device of claim 16, further comprising a second doped region selected from a doped source region and a doped drain region, wherein the first layer overlies the second doped region.

19. The device of claim 16, wherein the contact is formed by etching through another material using an etchant that is selective of the another material with respect to the first dielectric.

20. The device of claim 16, wherein the gate structure comprises a first conductive gate and a second conductive gate separated by an insulating material.
